(19) United States
(12) Patent Application Publication
(10) Pub. No.: US 2010/0224395 A1
(43) Pub. Date: Sep. 9, 2010

(54) MULTILAYER WIRING BOARD AND ITS MANUFACTURING METHOD

(75) Inventor: Hideki Higashitani, Kyoto (JP)

Correspondence Address: WENDEROTH, LIND & PONACK L.L.P., 1030 15th Street, N.W., Suite 400 East, Washington, DC, 20005-1503, US

(73) Assignee: PANASONIC CORPORATION, Osaka (JP)

(21) Appl. No.: 12/279,890

(22) PCT Filed: Mar. 27, 2007
(86) PCT No.: PCT/JP2007/056290

§ 371 Date: Aug. 19, 2008

(30) Foreign Application Priority Data
Mar. 28, 2006 (JP) 2006-087036
Mar. 28, 2006 (JP) 2006-087037

(51) Int. Cl. H05K 1/00; H05K 1/11; B32B 38/04; B32B 27/06

(52) U.S. Cl. 174/258; 174/262; 156/252; 156/242

(57) ABSTRACT

A multilayer wiring board includes a first wiring and a second wiring which are provided on both surfaces of an insulating board, a conductor passing through the insulating board for electrically connecting the first wiring to the second wiring, and an anchoring conductor passing through the insulating board. The anchoring conductor suppresses a distortion in the insulating board along the shearing direction of the insulating board and a deforming of the conductor, thus providing the multilayer wiring board with preferable electrical connection.

### TECHNICAL FIELD

The present invention relates to a multilayer wiring board in which wirings of multilayer are electrically connected to each other with inner via holes, and also relates to a method of manufacturing the board.

### BACKGROUND ART

As electronics devices have been recently had small sizes and high performance, multilayer wiring boards are demanded to be capable of having semiconductor chips, such as LSIs, mounted thereto densely and to be inexpensive not only in an industrial market but also in a consumer market. Such a multilayer wiring board includes wiring patterns arranged by fine pitches on plural layers and electrically coupled to each other reliably.

A conventional inter-layer connection used in a multilayer wiring board is implemented mainly by a metal plated inner wall of a through-hole. However, an inter-layer connection implemented by an inner via-hole has drawn attention because of the above demand. This inner via-hole connection allows electrodes of a multilayer wiring board to be connected at any wiring patterns. The inner via-hole connection provides a multilayer resin wiring board using an IVH structure in all layers. According to this connection, a through-hole provided in a multilayer wiring board is filled with a conductor so that only necessary layers can be connected. This structure allows the inner via-hole to be formed directly under a land, thereby allowing the board to have a small size and a high density.

A multilayer wiring board manufactured by processes shown in FIGS. 10A to 10I is proposed as the multilayer resin wiring board employing the IVH structure in all layers.

First, as shown in FIG. 10A, insulating board 21 is coated with protective films 22 on both surfaces thereof.

Then, as shown in FIG. 10B, through-holes 23 passing through all the board 21 and films 22 are formed with, for example, laser.

Then, as shown in FIG. 10C, each hole 23 is filled with conductor 29. Then, while protective films 22 are peeled off from both surfaces, wiring materials 25 having foil shapes are attached on both surfaces, thus providing the board shown in FIG. 10D. Wiring materials 25 are heated and pressed, so that materials 25 adhere to board 21 in the process shown in FIG. 10E. This process connects conductor 29 electrically to wiring materials 25 on both the surfaces.

Then, as shown in FIG. 10F, wiring materials 25 are etched to have patterns, thus providing double-sided wiring board 26.

Then, as shown in FIG. 10G, insulating boards 27 filled with conductors 24 and wiring materials 28 manufactured by the processes shown in FIGS. 10A to 10D are stacked on both surfaces of double-sided wiring board 26.

Then, wiring materials 28 and insulating board 27 are sandwiched by pressing plate 31 in the process shown in FIG. 10H, thus causing wiring materials 28 to adhere onto insulating board 27. Simultaneously to this, the double-sided wiring board adheres to board 27. In the process of heating and pressuring shown in FIG. 10H, conductor 24 connects wiring material 28 electrically to wiring 30 provided on double-sided wiring board 26, similarly to the process shown in FIG. 10E.

Then, wiring material 28 on the outermost layer is etched to have patterns, thereby providing a multilayer wiring board shown in FIG. 10I.

The above description relates to the wiring board having four layers. The number of the layers is not limited to four, but can be increased by repeating the processes discussed above.

As mentioned in the above conventional board, the multilayer wiring board is pressed with rigid and flat pressing plates, such as stainless steel plates, in order to provide the multilayer wiring board with flat and void-free surfaces.

However, in the process of heating and pressuring shown in FIG. 10H, double-sided wiring board 26 and pressing plates 31 change differently in dimensions from each other due to the difference of their materials.

This difference may produce a distortion along a shearing direction in insulating board 27, accordingly causing conductor 24 in board 27 to deform and displacing the layers from each other before providing the board shown in FIG. 10H.

FIG. 10H shows board 26 having a greater thermal expansion coefficient than plate 31, and conductor 24 tilts outward in double-sided wiring board 26. In the case that board 26 has a smaller thermal expansion coefficient than plate 31, conductor 24 tilts inward in double-sided wiring board 26.

The displacement of the layers displaces the position of conductor 24 formed at a predetermined position in insulating board 27. This displacement requires a wiring pattern (i.e., a land) which contacts conductor 24 to have a diameter large enough to offset this displacement. This prevents the wiring board from having a high density.

The deformation of the conductor along the shearing direction shown in FIG. 10H reduces a compressing force to be applied to the conductor in its thickness direction in the process of heating and pressuring. This prevents the wiring material from contacting the conductor strongly, accordingly having an electrical connection between the wiring material and the conductor deteriorate.

Patent document 1 below is known as related art to the present invention.

Patent Document 1: JP2005-150447A

### SUMMARY OF INVENTION

The present invention aims to provide a multilayer wiring board having a high density. The wiring board includes a conductor connecting wiring layers. The present invention also aims to provide a method of manufacturing of the board.

A multilayer wiring board includes a first wiring and a second wiring which are provided on both surfaces of an insulating board, a conductor passing through the insulating board for electrically connecting the first wiring to the second wiring, and an anchoring conductor passing through the insulating board. The anchoring conductor suppresses a distortion in the insulating board along the shearing direction of the insulating board and a deforming of the conductor, thus providing the multilayer wiring board with preferable electrical connection.

According to an aspect of the present invention, a multilayer wiring board includes a first insulating board having a first wiring on a surface thereof, a second insulating board for interlayer connection, a second wiring provided on a surface of the outer most layer. These elements stacked together by heating and pressuring. The first wiring is electrically connected to the second wiring via plural conductors passing through the second insulating board. The conductors include an anchoring conductor. The anchoring conductor allows the second insulating board to change in dimensions to follow the change of the first insulating board in dimensions during the applying of heat and pressure, and suppresses a distortion along a shearing direction. This prevents the conductors from deforming and allows the conductor to securely contact a wiring material, thus providing the multilayer wiring board with preferable electrical connection. The conductors provided in the insulating boards do not deform along the shearing direction, preventing the positions of the conductors from distorting. This reduces a clearance of a wiring pattern (land) contacting the conductors, accordingly providing the multilayer wiring board with a high density.

In a method of manufacturing a multilayer wiring board according to another aspect of the present invention, through-holes are formed in an insulating board, the through-holes are filled with conductors, the insulating board and a double-sided wiring board are stacked together to provide a laminated body, and heat and pressure are applied to the laminated body. The through-holes include a through-hole for forming an anchoring conductor. The anchoring conductor allows the insulating board to change in dimensions to follow the change of the double-sided wiring board in dimensions during the applying of heat and pressure, and suppresses a distortion in the insulating board along the shearing direction of the insulating board. This prevents the conductor from deforming, and accordingly, allows the conductors to securely contact a wiring material, thus providing the multilayer wiring board with preferable electrical connection.

Heat and pressure are applied to the insulating board sandwiched by the same material at both surfaces. This arrangement prevents the insulating board from having a distortion along the shearing direction, thus providing the conductors with stable electrical connection.

In a method of manufacturing a multilayer wiring board according to a further aspect of the present invention, conductors are formed on a wiring material, the wiring material, an insulating board, and a double-sided wiring board are stacked together to provide a laminated body, heat and pressure are applied to the laminated body. The conductors include an anchoring conductor. The anchoring conductor allows the insulating board to change in dimensions to follow the change of the double-sided wiring board in dimensions during the applying of heat and pressure, and suppresses a distortion of the insulating board along the shearing direction of the insulating board. This prevents the conductors from deforming, and allows the conductors to securely contact the wiring material, thus providing the multilayer wiring board with preferable electrical connection.

### BRIEF DESCRIPTION OF THE DRAWINGS

FIG. 1 is a sectional view of a multilayer wiring board in accordance with Exemplary Embodiment 1 of the present invention for illustrating the structure of the board.

FIG. 2 shows a sectional view of an insulating board of the multilayer wiring board of the present invention for illustrating the structure of the insulating board.

FIG. 3 is a partial sectional view of the multilayer wiring board in accordance with Embodiment 1 of the invention for illustrating a surface structure of the board.

FIG. 4 is a perspective view of the multilayer wiring board in accordance with Embodiment 1 of the invention for illustrating product portions.

FIG. 5A is a sectional view of a multilayer wiring board for illustrating a process for manufacturing the multilayer wiring board in accordance with Exemplary Embodiment 2 of the invention.

FIG. 5B is a sectional view of the multilayer wiring board for illustrating a process for manufacturing the multilayer wiring board in accordance with Embodiment 2 of the invention.

FIG. 5C is a sectional view of the multilayer wiring board for illustrating a process for manufacturing the multilayer wiring board in accordance with Embodiment 2 of the invention.

FIG. 5D is a sectional view of the multilayer wiring board for illustrating a process for manufacturing the multilayer wiring board in accordance with Embodiment 2 of the invention.

FIG. 5E is a sectional view of the multilayer wiring board for illustrating a process for manufacturing the multilayer wiring board in accordance with Embodiment 2 of the invention.

FIG. 5F is a sectional view of the multilayer wiring board for illustrating a process for manufacturing the multilayer wiring board in accordance with Embodiment 2 of the invention.

FIG. 5G is a sectional view of the multilayer wiring board for illustrating a process for manufacturing the multilayer wiring board in accordance with Embodiment 2 of the invention.

FIG. 5H is a sectional view of the multilayer wiring board for illustrating a process for manufacturing the multilayer wiring board in accordance with Embodiment 2 of the invention.

FIG. 5I is a sectional view of the multilayer wiring board for illustrating a process for manufacturing the multilayer wiring board in accordance with Embodiment 2 of the invention.

FIG. 6A is a sectional view of a multilayer wiring board for illustrating a process for manufacturing the multilayer wiring board in accordance with Exemplary Embodiment 3 of the invention.

FIG. 6B is a sectional view of the multilayer wiring board for illustrating a process for manufacturing the multilayer wiring board in accordance with Embodiment 3 of the invention.

FIG. 6C is a sectional view of the multilayer wiring board for illustrating a process for manufacturing the multilayer wiring board in accordance with Embodiment 3 of the invention.

FIG. 6D is a sectional view of the multilayer wiring board for illustrating a process for manufacturing the multilayer wiring board in accordance with Embodiment 3 of the invention.

FIG. 6E is a sectional view of the multilayer wiring board for illustrating a process for manufacturing the multilayer wiring board in accordance with Embodiment 3 of the invention.

FIG. 6F is a sectional view of the multilayer wiring board for illustrating a process for manufacturing the multilayer wiring board in accordance with Embodiment 3 of the invention.

FIG. 6G is a sectional view of the multilayer wiring board for illustrating a process for manufacturing the multilayer wiring board in accordance with Embodiment 3 of the invention.

FIG. 7A is a sectional view of a multilayer wiring board for illustrating a process for manufacturing the multilayer wiring board in accordance with Exemplary Embodiment 4 of the invention.

FIG. 7B is a sectional view of the multilayer wiring board for illustrating a process for manufacturing the multilayer wiring board in accordance with Embodiment 4 of the invention.

FIG. 7C is a sectional view of the multilayer wiring board for illustrating a process for manufacturing the multilayer wiring board in accordance with Embodiment 4 of the invention.

FIG. 7D is a sectional view of the multilayer wiring board for illustrating a process for manufacturing the multilayer wiring board in accordance with Embodiment 4 of the invention.

FIG. 7E is a sectional view of the multilayer wiring board for illustrating a process for manufacturing the multilayer wiring board in accordance with Embodiment 4 of the invention.

FIG. 7F is a sectional view of the multilayer wiring board for illustrating a process for manufacturing the multilayer wiring board in accordance with Embodiment 4 of the invention.

FIG. 7G is a sectional view of the multilayer wiring board for illustrating a process for manufacturing the multilayer wiring board in accordance with Embodiment 4 of the invention.

FIG. 8A is a sectional view of a multilayer wiring board for illustrating a process for manufacturing the multilayer wiring board in accordance with Exemplary Embodiment 5 of the invention.

FIG. 8B is a sectional view of the multilayer wiring board for illustrating a process for manufacturing the multilayer wiring board in accordance with Embodiment 5 of the invention.

FIG. 8C is a sectional view of the multilayer wiring board for illustrating a process for manufacturing the multilayer wiring board in accordance with Embodiment 5 of the invention.

FIG. 8D is a sectional view of the multilayer wiring board for illustrating a process for manufacturing the multilayer wiring board in accordance with Embodiment 5 of the invention.

FIG. 8E is a sectional view of the multilayer wiring board for illustrating a process for manufacturing the multilayer wiring board in accordance with Embodiment 5 of the invention.

FIG. 8F is a sectional view of the multilayer wiring board for illustrating a process for manufacturing the multilayer wiring board in accordance with Embodiment 5 of the invention.

FIG. 8G is a sectional view of the multilayer wiring board for illustrating a process for manufacturing the multilayer wiring board in accordance with Embodiment 5 of the invention.

FIG. 8H is a sectional view of the multilayer wiring board for illustrating a process for manufacturing the multilayer wiring board in accordance with Embodiment 5 of the invention.

FIG. 8I is a sectional view of the multilayer wiring board for illustrating a process for manufacturing the multilayer wiring board in accordance with Embodiment 5 of the invention.

FIG. 9A is a sectional view of a multilayer wiring board for illustrating a process for manufacturing the multilayer wiring board in accordance with Exemplary Embodiment 6 of the invention.

FIG. 9B is a sectional view of the multilayer wiring board for illustrating a process for manufacturing the multilayer wiring board in accordance with Embodiment 6 of the invention.

FIG. 9C is a sectional view of the multilayer wiring board for illustrating a process for manufacturing the multilayer wiring board in accordance with Embodiment 6 of the invention.

FIG. 9D is a sectional view of the multilayer wiring board for illustrating a process for manufacturing the multilayer wiring board in accordance with Embodiment 6 of the invention.

FIG. 9E is a sectional view of the multilayer wiring board for illustrating a process for manufacturing the multilayer wiring board in accordance with Embodiment 6 of the invention.

FIG. 9F is a sectional view of the multilayer wiring board for illustrating a process for manufacturing the multilayer wiring board in accordance with Embodiment 6 of the invention.

FIG. 9G is a sectional view of the multilayer wiring board for illustrating a process for manufacturing the multilayer wiring board in accordance with Embodiment 6 of the invention.

FIG. 9H is a sectional view of the multilayer wiring board for illustrating a process for manufacturing the multilayer wiring board in accordance with Embodiment 6 of the invention.

FIG. 9I is a sectional view of the multilayer wiring board for illustrating a process for manufacturing the multilayer wiring board in accordance with Embodiment 6 of the invention.

FIG. 10A is a sectional view of a conventional multilayer wiring board for illustrating a process for manufacturing the multilayer wiring board.

FIG. 10B is a sectional view of the conventional multilayer wiring board for illustrating a process for manufacturing the multilayer wiring board.

FIG. 10C is a sectional view of the conventional multilayer wiring board for illustrating a process for manufacturing the multilayer wiring board.

FIG. 10D is a sectional view of the conventional multilayer wiring board for illustrating a process for manufacturing the multilayer wiring board.

FIG. 10E is a sectional view of the conventional multilayer wiring board for illustrating a process for manufacturing the multilayer wiring board.

FIG. 10F is a sectional view of the conventional multilayer wiring board for illustrating a process for manufacturing the multilayer wiring board.

FIG. 10G is a sectional view of the conventional multilayer wiring board for illustrating a process for manufacturing the multilayer wiring board.

FIG. 10H is a sectional view of the conventional multilayer wiring board for illustrating a process for manufacturing the multilayer wiring board.

FIG. 10I is a sectional view of the conventional multilayer wiring board for illustrating a process for manufacturing the multilayer wiring board.

### REFERENCE NUMERALS

1 Insulating Board
2 Protective Film
3 Through-Hole
4 Conductor
5 Wiring Material
6 Double-Sided Wiring Board
7 Insulating Board
8 Wiring Material
10 Wiring
11 Pressing Plate
12 Wiring
13 Core
14 Thermosetting Resin
15 Product portion
16 Multilayer Wiring Board
17 Conductor
18 Conductor

### DETAIL DESCRIPTION OF THE PREFERRED EMBODIMENTS

According to an aspect of the present invention, a multilayer wiring board includes a first insulating board having a first wiring on a surface of the first board, a second insulating board for interlayer connection, and a second wiring provided on a surface of the outer most layer. These elements are stacked together by applying heat and pressure. The first wiring is electrically connected to the second wiring via plural conductors passing through the second insulating board. The multiple conductors include an anchoring conductor. The anchoring conductor allows the second insulating board to change in dimensions to follow the change of the first insulating board in dimensions during the applying of heat and pressure, suppressing a distortion along a shearing direction. This prevents the conductor from deforming, and allows the conductors to securely contact the wiring material, thus providing the multilayer wiring board with preferable electrical connection. The conductors formed in the insulating boards do not deform along the shearing direction, accordingly suppressing a distortion of the coordinate positions of the conductors. This reduces a clearance of the wiring pattern, i.e. land, contacting the conductors, accordingly providing the multilayer wiring board with a high density.

The distortion along the shearing direction is a distortion in parallel with the surface of the board and tilts the conductors having columnar shapes.

A multilayer wiring board according to another aspect of the present invention includes the anchoring conductor has a diameter different from diameters of conductors other than the anchoring conductor. The anchoring conductor, upon having a larger diameter, is located at a position which does not influence a product design. This arrangement allows the second electrical insulating board to hold a core securely, thereby preventing the conductors in the second insulating from deforming.

A multilayer wiring board according to a further aspect of the present invention includes the anchoring conductor located at a position other than a product portion of the multilayer wiring board. The anchoring conductor for holding the core of the second insulating board is located at the position other than the product portion of the board, and hence, allows the second board to hold the core securely, accordingly preventing the conductors in the second insulating board from deforming.

A multilayer wiring board according to a further aspect of the present invention includes the conductors formed by hardening conductive paste containing thermosetting resin. The conductors made of the conductive paste can be formed by a printing method to provide electrical interlayer connection, thus manufacturing the multilayer wiring board at high productivity.

A multilayer wiring board according to a further aspect of the present invention includes the conductors hardened during the applying of heat and pressure. The conductive paste and the second insulating board can be hardened simultaneously, thereby manufacturing the multilayer wiring board at high productivity.

In a multilayer wiring board according to a further aspect of the present invention, the conductors are hardened before heat and pressure are applied to the insulating board. The conductive paste is hardened before the second insulating board is bonded to the first insulating board, and hence, the conductor is rigid enough to hold the core, accordingly preventing the conductor efficiently from deforming.

According to a further aspect of the present invention, the second insulating board having the conductors for interlayer connection includes a core and a thermosetting resin. The thermosetting resin is melted during the applying of heat and pressure. The viscosity of the resin lowers to the minimum melting viscosity and then rises during the resin is hardened. The minimum melting viscosity is a temperature at which the conductor can hold the core. Even when the viscosity of the thermosetting resin decreases to the minimum melting viscosity, the conductor holds the core, and suppresses a distortion in the insulating board along the shearing direction of the insulating board. This prevents the conductor from deforming, hence providing the multilayer wiring board with preferable electrical connection. When the thermosetting resin softens and has its viscosity reaching the minimum melting viscosity, the conductor has a small rigidity at high temperatures.

The expression that the conductor holds the core means that the conductor is compressed between the first wiring and the second wiring and functions as a pile against the core. In other words, the conductor exhibits anchoring effect so that the second insulating board changes in dimension to follow the change of the first insulating board in dimensions.

According to a further aspect of the present invention, the first insulating board having a first wiring on its surface is a multilayer circuit board. A conductive material on the outer most layer of a multilayer circuit board may deform easily. The outer most layer can change in dimensions to follow the change of the second insulating board in dimensions, and prevents the conductor from deforming, hence providing the multilayer wiring board with preferable electrical connection.

According to a further aspect of the present invention, conductors are provided in all the layers, providing the multilayer wiring board with reliable electrical connection.

In a method of manufacturing a multilayer wiring board according to a further aspect of the present invention, through-holes are provided in an insulating board. The through-holes are with conductors. The insulating board and a double-sided wiring board are stacked together to form a laminated body. Heat and pressure are applied to the laminated body. The through-holes include a through-hole to be filled with an anchoring conductor. The anchoring conductor allows the insulating board change in dimensions to follow the change of the double-sided wiring board in dimensions during the applying of heat and pressure, hence suppressing a distortion in the insulating board along the shearing direction. This prevents the conductors from deforming, and allows the conductors to securely contact the wiring material, thus providing the multilayer wiring board with preferable electrical connection.

The heat and pressure may be applied to the insulating board sandwiched by the same materials at both surfaces of the board. This arrangement suppresses a distortion in the insulating board along the shearing direction, thus allowing the conductors to perform stable electrical connection.

In a method of manufacturing a multilayer wiring board according to a further aspect of the present invention, conductors are formed on a wiring material. The wiring material, an insulating board, and a double-sided wiring board are stacked together to provide a laminated body. Heat and pressure are applied to the laminated body. The wiring material is patterned. The conductors include an anchoring conductor. The anchoring conductor allows the insulating board to change in dimensions to follow the change of the double-sided wiring board in dimensions during the applying of heat and pressure. This suppresses a distortion in the insulating board along the shearing direction of the insulating board, and prevents the conductors from deforming. The conductors accordingly contact the wiring material securely, thus providing the multilayer wiring board with preferable electrical connection.

In a method of manufacturing a multilayer wiring board according to a further aspect of the present invention, conductors are formed on a double-sided wiring board. The double-sided wiring board, an insulating board, and a wiring material are stacked together to provide a laminated body. Heat and pressure are applied to the laminated body. The wiring material is patterned. The conductors include an anchoring conductor. The anchoring conductor allows the insulating board to change in dimensions to follow the change of the double-sided wiring board in dimensions during the applying of heat and pressure. This arrangement suppresses a distortion in the insulating board along the shearing direction of the insulating board, and prevents the conductors from deforming. This allows the conductors to contact the wiring material securely, thus providing the multilayer wiring board with preferable electrical connection. This method can eliminate a process for turning over the board after the forming of the conductors, thus being simplified.

According to a further aspect of the present invention, the insulating board may include a core and a thermosetting resin. A viscosity of the thermosetting resin lowers to a minimum melting viscosity during the applying of the heat and the pressure and then rises while the resin hardens. The minimum melting viscosity allows the conductor to hold the core. The conductor can hold the core even when the viscosity of the thermosetting resin is the minimum melting viscosity. This arrangement suppresses a distortion in the insulating board along the shearing direction of the insulating board, and prevents the conductors from deforming, thus providing the multilayer wiring board with preferable electrical connection.

According to a further aspect of the present invention, the heat and the pressure may be applied to the laminated body via a pressing plate, such that a shift may be produced between the laminated body and the pressing plate before a temperature reaches a shift starting temperature. The shift starting temperature is a temperature at which the shift occurs in the laminated body along a shearing direction due to a difference between thermal expansion properties of the pressing plate and the double-sided wiring board when the insulating board softens due to a temperature rise by applying of the heat. The shift between the pressing plate and the wiring material at a temperature during a temperature rise and lower than the shift producing temperature absorbs a stress along the shearing direction and applied to the insulating board at high temperatures. This prevents the conductors from deforming, thus providing the multilayer wiring board with preferable electrical connection.

According to a further aspect of the present invention, the shift may be produced by applying a pressure lower than a pressure applied to the insulating board at the minimum melting viscosity. The pressure applied during the applying of heat and pressure is released at a temperature lower than the shift starting temperature, so that the shift can be produced between the pressing plate and the wiring material. This process easily prevents the conductors from deforming, thus providing the multilayer wiring board with preferable electrical connection.

According to a further aspect of the present invention, the heat and the pressure are applied to the laminated body via a pressing plate. The pressing plate has a thermal expansion coefficient substantially identical to a thermal expansion coefficient of the double-sided wiring board of the laminated body. The pressing plate and the double-sided wiring board have substantially identical thermal expansion coefficients at a temperature lower than the shift starting temperature, hence reducing the stress along the shearing direction applied to the insulating board. This prevents the conductors from deforming, thus providing the multilayer wiring board with preferable electrical connection.

According to a further aspect of the present invention, the pressing plate may have a multilayer structure including a rigid portion and a thermal expansion adjusting portion. The rigid portion is provided at a surface of the pressing plate. The thermal expansion adjusting portion is provided in the pressing plate. This pressing plate has its thermal expansion coefficient which can be precisely adjusted, thereby reducing the difference between thermal expansion properties of the double-sided wiring board and the pressing plate. This prevents the conductors from deforming, and provides the multilayer wiring board with preferable electrical connection.

According to a further aspect of the present invention, the double-sided wiring board may be a multilayer circuit board. This arrangement provides a multilayer wiring board with a high density while the conductors maintain stable electrical connection.

A multilayer wiring board according to a further aspect of the present invention includes a first insulating board having a first wiring on a surface thereof, a second insulating board for interlayer connection, and a second wiring disposed on an outer most surface. The elements are stacked together by heating and pressuring. The first wiring and the second wiring are electrically connected to each other via a conductor passing through the second insulating board. The second insulating board changes in dimensions to follow the change of the first insulating board in dimensions due to expansion and contraction of the first insulating board. The second insulating board changes in dimensions to follow the change in dimensions during the applying of heat and pressure, thereby suppressing a distortion in the second insulating board along the shearing direction of the second insulating board. This prevents the conductor from deforming and allows the conductors to securely contact the wiring material, thereby providing the multilayer wiring board with preferable electrical connection. The conductor formed in the insulating board does not deform along the shearing direction, and suppresses a distortion of a coordinate position of the conductor. This allows a wiring pattern (land) contacting the conductor to have a small clearance, accordingly providing the multilayer wiring board with a high density.

In a method of manufacturing a multilayer wiring board according to a further aspect of the present invention, a through-hole is formed in an insulating board. The through-hole is filled with a conductor. The insulating board and a wiring material are stacked onto a surface of a double-sided wiring board to form a laminated body. Heat and pressure are applied to the laminated body to adhere the laminated body to the double-sided wiring board. The wiring material is patterned. During the applying of heat and pressure, the insulating board changes in dimensions to follow the change of the double-sided wiring board in dimensions. This suppresses a distortion in the insulating board along a shearing direction of the insulating board, and prevents the conductor from deforming. This allows the conductor to securely contact the wiring material, thus providing the multilayer wiring board with preferable electrical connection.

In a method of manufacturing a multilayer wiring board according to a further aspect of the present invention, a through-hole is formed in an insulating board. The through-hole is filled with a conductor. Plural double-sided wiring boards sandwich the insulating board between the double-sided wiring boards to form a laminated body. Heat and pressure are applied to the laminated body. During the applying of heat and pressure, the insulating board changes in dimensions to follow the changes of the double-sided wiring boards in dimensions. The heat and pressure are applied to the insulating board sandwiched by the same materials. This arrangement reduces a distortion along the shearing direction, thus allowing the conductor to have stable electrical connection.

In a method of manufacturing a multilayer wiring board according to a further aspect of the present invention, a through-hole is formed in an insulating board. The through-hole is filled with a conductor. Plural double-sided wiring boards and a wiring material are stacked together via the insulating board to provide a laminated body. Heat and pressure are applied to the laminated body. The wiring material is patterned. During the applying of heat and pressure, the insulating board changes in dimensions to follow the change of the double-sided wiring boards in dimensions. This suppresses a distortion in the insulating board along the shearing direction of the insulating board, prevents the conductor from deforming. This allows the conductor to securely contact the wiring material, thus providing the multilayer wiring board with preferable electrical connection for a short time.

In a method of manufacturing a multilayer wiring board according to a further aspect of the present invention, a conductor is formed on a wiring material. The wiring material, an insulating board, and a double-sided wiring board are stacked together to provide a laminated body. Heat and pressure are applied to the laminated body. The wiring material is patterned. During the applying of heat and pressure, the insulating board changes in dimensions to follow the change of the double-sided wiring boards in dimensions. This suppresses a distortion in the insulating board along the shearing direction of the insulating board, and prevents the conductor from deforming. This allows the conductor to securely contact the wiring material, thus providing the multilayer wiring board with preferable electrical connection.

In a method of manufacturing a multilayer wiring board according to a further aspect of the present invention, a conductor is formed on wiring material. A double-sided wiring board, the insulating board, and the wiring material are stacked together to provide a laminated body. Heat and pressure are applied to the laminated body. The wiring material is patterned. During the applying of heat and pressure, the insulating board changed in dimensions to follow the change of the double-sided wiring board in dimensions. This suppresses a distortion in the insulating board along a shearing direction of the insulating board, and prevents the conductor from deforming. This allows the conductor to securely contact the wiring material, thus providing the multilayer wiring board with preferable electrical connection. During the stacking, surfaces having the conductor formed thereon face toward one direction. This arrangement eliminates a process for turning over the laminated body after the forming of the conductor, thus simplifying the manufacturing method.

Exemplary embodiments of the present invention will be described below with reference to the accompanying drawings.

### EXEMPLARY EMBODIMENT 1

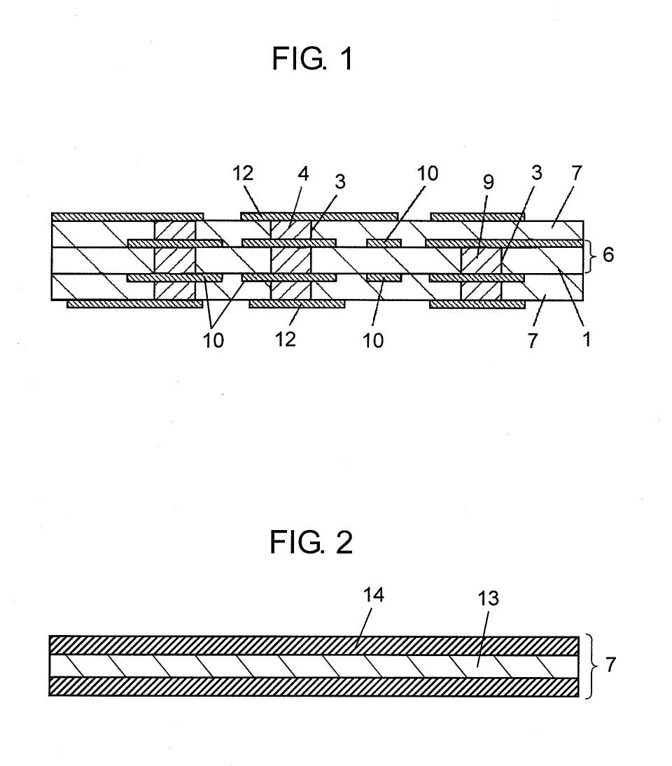

FIG. 1 is a sectional view of a multilayer wiring board in accordance with Exemplary Embodiment 1 of the present invention. The multilayer wiring board includes conductors 4 and 9 formed in through-holes 3 provided to first insulating board 1 and second insulating board 7, respectively, to have interlayer electrical connection at any place, thereby accommodating wirings densely.

This multilayer wiring board includes double-sided wiring board 6 as a core and second insulating boards 7 attached onto both surfaces of board 6 with heat and pressure. Double-sided wiring board 6 includes first insulating board 1 and first wiring 10 formed on both surfaces of board 1. Each through-hole 3 provided in second insulating board 7 is filled with conductor 4 to provide board 7 with interlayer connecting function.

A feature of the present invention is that the attaching with heat and pressure allows second insulating board 7 to change in dimensions to follow the expansion and contraction of double-sided wiring board 6. This feature prevents second insulating board 7 from having a distortion along a shearing direction of board 7, accordingly preventing conductors 4 from deforming. The distortion of board 7 along the shearing direction is a distortion of board 7 in parallel with a surface of board 7, and tilts conductors 4 and 9 having columnar shapes.

As a result, conductor 4 maintains its compressing force along the thickness direction. This provides secure contact between conductors 4 and first wiring 10 as well as between conductors 4 and second wiring 12, i.e. the surface of the outer most layer, thus providing the multilayer wiring board with preferable electrical connection.

Second insulating board 7 includes core 13 and thermo-setting resin 14, as shown in FIG. 2. In FIG. 2, the border between core 13 and resin 14 is clearly shown, however, the present invention is not limited to this. For instance, core 13 may be impregnated with resin 14. In this case, core 13 impregnated with resin 14 may preferably include layers made of thermosetting resin 14 on surfaces of core 13.

During the applying of the heat and pressure, thermosetting resin 14 melts to have a viscosity which is reduced to the minimum melting viscosity and then rises to be hardened. Resin 14 preferably holds core 13 at the minimum melting viscosity.

The viscosity of the thermosetting resin is determined such that the resin can hold the core of the insulating board even at the lowest viscosity, i.e. the minimum melting viscosity. This arrangement prevents the insulating board from distorting along the shearing direction of the insulating board, accordingly prevents the conductors from deforming.

The expression “thermosetting resin 14 can hold core 13” means that core 13 surrounded by resin 14 changes in dimensions to follow the change of resin 14 in dimensions even if resin 14 is softened with heat and pressure. In other words, the minimum melting viscosity of resin 14 is determined to be a rather high viscosity to restrict the changes in dimensions according to the thermal expansion coefficient of the core.

To be more specific, thermosetting resin 14, upon softening, has a small rigidity, and changes in dimensions to follow the change of first insulating board 1. Thus, core 13 of second insulating board 7 changes in dimensions to follow the change of first insulating board 1 in dimensions.

Core 13 is made of woven fabric or non-woven fabric of glass fiber, woven fabric or non-woven fabric of aramid fiber, fiber or non-woven fabric of fluorine-based resin, or heat resisting film or porous film made from polyimide resin, fluorine-based resin, or liquid crystal polymer.

Thermosetting resin 14 is made of epoxy resin, polyimide resin, PPE resin, PPO resin, or phenol resin. Resin 14 may preferably include filler to adjust properties of melting or hardening of the thermosetting resin easily. The filler may employ inorganic material, such as alumina, silica, or aluminum hydroxide.

An object of mixing the thermosetting resin with the filler is to physically adjust the fluidity of the resin. The filler is not limited to the above materials as long as the filler achieves this object.

The filler has a diameter ranging preferably from 0.5 to 5 μm. The diameter within this range allows the filler to disperse in the resin.

The mixing of the thermosetting resin with filler increases a melting time during the applying of heat and pressure, and the filler can suppress the reducing of the viscosity of the resin. This arrangement allows wiring 10 to be embedded in insulating board 7 while preventing insulating board 7 from deforming along the shearing direction of insulating board 7.

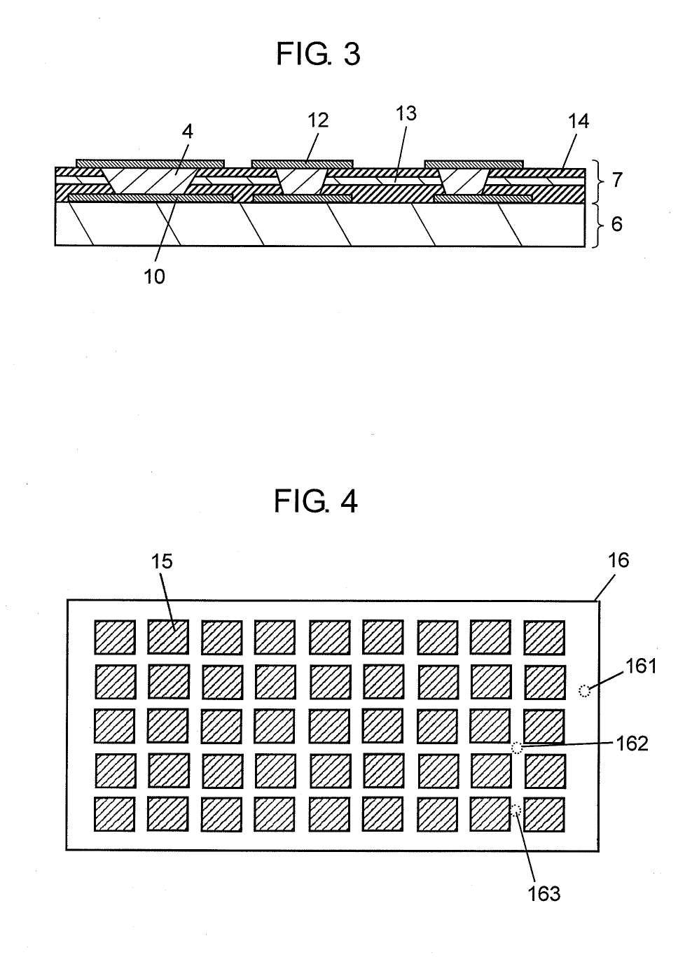

FIG. 3 is an enlarged view of a surface layer of second insulating board 7 attached onto each surface of double-sided wiring board 6.

As shown in FIG. 3, conductor 4 for interlayer connection passing through second insulating board 7 connects electrically connection between first wiring 10 and second wiring 12, i.e. the surface of the outer most layer, thereby providing the a multilayer wiring board with preferably electrical connection.

Conductor 4 holds core 13 preferably even if the thermosetting resin has the minimum melting viscosity.

The expression, “conductor 4 holds core 13” means that, when thermosetting resin 14 softens and has a viscosity reaching the minimum melting viscosity, conductor 4 functions as a pile to core 13 of second insulating board 7. Having a rigidity which does not decrease even at high temperatures, conductor 4 maintains compressing between first wiring 10 and second wiring 12, and thus, functions as the pile to core 13 of second insulating board 7.

To be more specific, when board 7 is attached onto board 6 with heat and pressure, a compressing force is applied to conductor 4. The compressing force allows conductor 4 to anchor between wiring 12 and wiring 10 on board 6. The anchoring of conductor 7 allows second insulating board 7 to change in dimensions to follow the change of the first insulating board, i.e., double-sided wiring board 6, in dimensions.

Plural conductors 4 are provided in second insulating board 7. Conductors 4 are placed at positions which do not influence a product design in order to increase the anchoring effect to core 13. Conductors 4 may have diameters different from those of other conductors. Conductors 4 have larger diameters as to increase the anchoring effect. Some of conductors 4 connecting wiring 12 to wiring 10 function as conductors 4 for anchoring.

A position which does not influence the product design is a position which is in a product portion and which has a low wiring density, so that a wiring pattern (land) which contacts the conductor does not reduce wirings in the product portion even if the pattern (land) has a large diameter.

The expression, “product portion” means that a unit of product having electronic components mounted on the board to exhibit a circuit function. The product portion is incorporated into an electronic device.

Conductors 4 (referred to as anchoring conductors) for holding core 13 are also preferably provided at positions other than the product portion of the multilayer wiring board.

As shown in FIG. 4, multilayer wiring board 16 often includes plural product portions 15. The product portions are cut out from the multilayer wiring board by a contour processing with, for example, a die or a router. Multilayer wiring board 16 thus has regions which do not included in the product portions. The regions include periphery 161 and regions 162 and 163 between product portions 15. Anchoring conductor 4 is provided in these regions to exhibit the effect. In this case, anchoring conductor 4 may not connect between wirings 10 and 12 in product portions 15. Conductors 4 thus hold the core securely in insulating board 7.

Wiring 10 contacting anchoring conductor 4 placed at the regions other than the product portions may be preferably provided. Wiring 10 contacting anchoring conductor 4 provides conductors 4 with a compressing force by a thickness of wiring 10, thereby increasing the anchoring effect.

Anchoring conductor 4 is placed in the regions other than the product portions, thereby increasing the anchoring effect. The number and the diameters of conductors 4 provided in board 7 may be determined appropriately to allow the core to be held by only conductors 4 placed in the product portions.

An example will be described below. First insulating board 1, i.e. double-sided wiring board 6, is made of glass epoxy hand has a thickness of 60 μm. Insulating board 7 is made of glass epoxy board and has a thickness of 40 μm. Conductor 4 is made of conductive paste including epoxy resin and copper particles having diameters of 150 μm. When the average number of the conductors in a large size wiring board is larger than 10/cm², the conductors exhibit the anchoring effect. When the number of the conductors is larger than 20/cm², the conductors exhibit a uniform anchoring effect within the surface of the wiring board.

Wiring 12 shown in FIG. 1 is formed by attaching a wiring material having a foil shape onto the surface of board 7, attaching a photo sensitive resist, exposing and developing the resist, etching the exposed portions of the material, and then removing the resist. A film mask is used for exposing the photo sensitive resist, so that a pattern for shielding light is transcribed onto the film, thereby providing the wiring pattern.

The position of the wiring pattern (land) contacting the conductor is drawn on the film mask in advance. If the conductor deforms as described above, the diameter of the wiring pattern (land) contacting the conductor is required to be large enough to offset the distortion.

However, in the multilayer wiring board in accordance with Embodiment 1, the conductors provided in the insulating board does not deform along the shearing direction, thus having a position prevented from distorting. This allows the wiring pattern (land) contacting the conductor may be designed with a small clearance, accordingly providing the multilayer wiring board with a high density.

In double-sided wiring board 6 as the core shown in FIG. 1, conductor 9 filling through-hole 3 performs electrical connection. The structure of double-sided wiring board 6 as the core is not limited to this. For instance, double-sided wiring board 6 may include a conductor formed on an inner wall of the through-hole by, e.g. plating, providing the same effects.

The core is not limited to the double-sided wiring board, but may be a multilayer circuit board.

In the case that the multilayer circuit board is used as the core, the core is more rigid, so that a large stress along the shearing direction is often produced in second insulating board 7, i.e. the outer most layer, hence causing the conductor to deform.

According to the embodiment, the second insulating board changes in dimensions to follow the change of the first insulating board, the core, in the dimensions, thereby preventing the conductor from deforming even if the multilayer circuit board, which tends to cause the conductor to deform, is used. According to the embodiment, the wiring board can have eight or more layers.

The multilayer circuit board including an insulating board having the through-holes filled with the conductors in all layers provides the multilayer wiring board with a high density.

Conductor 4 is made of conductive paste including conductive particles and thermosetting resin. This paste is preferably hardened when board 7 is attached onto board 6. The paste which is hardened before board 7 is attached onto board 6 with heat and pressure increases the rigidity of the conductor, accordingly increasing the anchoring effect of the conductor.

The conductive paste may be hardened simultaneously when insulating board 7 is hardened. In this case, a hardening process can be simplified, providing the multilayer wiring board with high productivity. When the conductive paste is hardened together with board 7, a hardening start temperature of the paste may be preferably lower than that of insulating board 7. The conductive paste starts being hardened earlier than board 7, and thereby, applies a large compressing force to the paste when the viscosity of board 7 lowers, thus increasing the anchoring effect of the conductor.

As discussed above, according to this embodiment, the conductors are prevented from deforming along the shearing direction, thus providing the multilayer wiring board with reliable electrical connection. Further, the wiring patterns (lands) contacting the conductors can be designed with a smaller clearance, accordingly providing the multilayer wiring board with a high density.

### EXEMPLARY EMBODIMENT 2

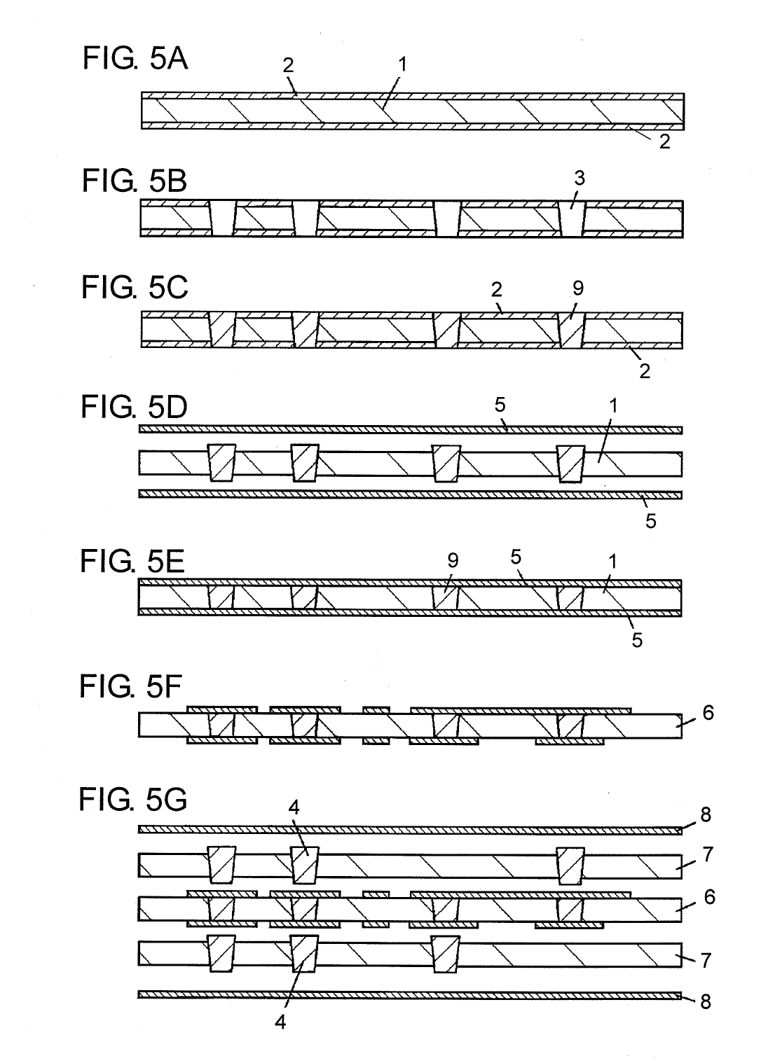

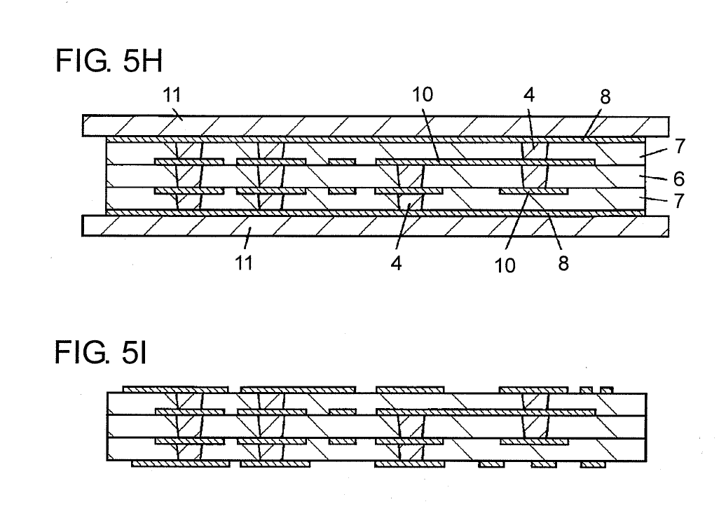

A procedure of manufacturing the multilayer wiring board of the present invention will be described below with reference to FIGS. 5A to 5I. Components identical to those of the conventional wiring board and the wiring board according to Embodiment 1 will be concisely described. Terms in the following description have been defined in Embodiment 1.

First, as shown in FIG. 5A, protective films 2 are attached onto both surfaces of insulating board 1.

Insulating board 1 is made of composite material containing fiber and impregnating resin. For instance, the fiber may employ woven fabric or non-woven fabric of glass fiber, aramid fiber, fluorine fiber, or liquid crystal polymer. The impregnating resin may employ epoxy resin, polyimide resin, PPE resin, PPO resin, or phenol resin.

In order to provide electrical connection with the conductor filling the through-hole, the board can be compressed, namely, has a thickness reduced while the board is hardened with heat and pressure. Specifically, the board may be made preferably of porous material which includes the fiber impregnated with the resin and which has voids therein even after the impregnating of the resin.

Alternatively, the insulating board may include a film and adhesive layers on both surfaces of the film, that is, may have a three layer construction which is generally used as a flexible wiring board. Specifically, the film may be made of thermosetting resin, such as epoxy, or thermoplastic resin, such as fluorine resin, polyimide resin, or liquid crystal polymer. The adhesive layers are provided on both surfaces of the film, thus providing the insulating board.

Protective film 2 may be made mainly of polyethylene terephthalate (PET) or polyethylene naphthalate (PEN). Protective film 2 is attached onto each surface of board 1 by lamination, providing a method of manufacturing the board simply at high productivity.

Then, as shown in FIG. 5B, through-hole 3 passing through both of protective film 2 and insulating board 1 is provided. Through-hole 3 can be formed by punching, drilling, or laser processing. Carbon-gas laser or YAG laser can form through-hole 3 with a smaller diameter in a short time, accordingly manufacturing the board at high productivity. Through-hole 3 may preferably have a tapered shape having both ends thereof have different diameters in order to increase a density of the wiring board. When the laser processing is used, a pulse irradiation condition and a focus are adjusted appropriately to provide the through-hole having the tapered shape having a diameter of a side of the through-hole facing the laser is greater than that of a side of the through-hole opposite to the laser.

Then, as shown in FIG. 5C, through-hole 3 is filled with conductor 9. Use being made of conductive paste, conductor 9 may be formed by a printing method preferably at high productivity. The conductive paste contains thermosetting resin and conductive particles of copper, silver, gold, or alloy of these metals. Conductor 9 may not be made of these materials as far as it can maintain electrical connection. For instance, through-hole 3 can be filled with conductive particles.

The diameter of the conductive particles is preferably determined in response to the diameter of through-hole 3. For instance, the conductive particles having an average diameter ranging from 1 to 5 μm are preferably used for a through-hole having a diameter ranging from 50 to 200 μm. The conductive particles are preferably screened to have uniform diameters for stabilizing electrical connection.

Protective films 2 protect the insulating board from conductor 9 tending to attach to the surfaces of the board, and also secure the amount of conductor 9 to filling through-hole 3.

Then, protective films 2 are removed from insulating board 1, and wiring materials 5 are attached onto both surfaces of board 1, thereby providing the board shown in FIG. 5D. Since the amount of conductor 9 has been secured by protective film 2, conductor 9 protrudes from the surface of board 1 by the thickness of film 2.

Wiring material 5 may be made of copper foil having rough surfaces. The surfaces of the foil may be preferably coated with surface treatment films of Cr, Zn, Ni, Co, Sn, oxide of them or alloy of these metals. The films increase adherence of material 5 to the resin.

However, upon having an excessive amount, the surface treatment films may prevent the material 5 from being connected electrically to conductor 9, thus having reliability of electrical connection in the multilayer board deteriorate since the films have an insulating property.

Each surface treatment film may have a small thickness not larger than 50 nm to expose base metal (copper) of the wiring material from the surface treatment films.

Then, as shown in FIG. 5E, wiring materials 5 are adhered onto both surfaces of insulating board 1 with heat and pressure, and compresses conductor 9 along the thickness direction, thereby connecting electrically between wiring materials 5 provided on both surfaces.

Then, a photosensitive resist is formed on the entire surface of wiring material 5, exposed, and developed, thereby forming a pattern. The resist can employ a dry film type or a liquid type. If a fine pattern is not necessary, material of the resist can be printed by a screen printing method instead of the photosensitive material.

Then, wiring material 5 is etched, and the photosensitive resist is removed, thus providing double-sided wiring board 6 shown in FIG. 5F.

Then, as shown in FIG. 5G, insulating board 7 with conductor 4 and wiring material 8 are attached onto both surfaces of double-sided wiring board 6, thus providing a laminated body. Insulating board 7 is manufactured by the same processes as shown in FIGS. 5A to 5D. Wiring material 8 may be made of the same copper foil as that shown in FIG. 5D. In the case that wiring material 8 is used as the outer most layer of the multilayer wiring board, wiring material 8 may be made of a foil having one surface roughened and another surface remaining flat, i.e. a single-surface luster foil, to have an electronic component mounted on the flat surface of the foil.

In the process shown in FIG. 5H, the laminated body is sandwiched with pressing plates 11 vertically, and heat and pressure are applied to wiring material 8, thereby bonding wiring material 8 to insulating board 7. At this moment, double-sided wiring board 6 is bonded to insulating board 7.

During the applying of heat and pressure, insulating board 7 changes in dimensions to follow the change of double-sided wiring board 6 in dimensions, and is prevented from distorting along the shearing direction of board 7, thus preventing conductor 9 from deforming. This assures a secure contact between the conductor and the wiring material, thus providing the multilayer wiring board with preferable electrical connection.

The conductor formed in the insulating board does not deform along the shearing direction, having a position prevented from being displaced. This reduces a clearance of the wiring pattern (land) contacting the conductor, accordingly providing the multilayer wiring board with a high density.

Then, as shown in FIG. 5I, the wiring material is etched to have a pattern, providing the multilayer wiring board shown in FIG. 5I.

During the process of applying heat and pressure shown in FIG. 5H, pressing plates 11 and double-sided wiring board 6 in the laminated body expand by their own thermal expansion coefficients, thereby producing a stress.

Specifically, the difference in the thermal expansion coefficients between pressing plates 11 and double-sided wiring board 6 produces a stress to displace, along the shearing direction, insulating board 7 located between each pressing plate 11 and insulating board 6. If insulating board 7 softens drastically due to a temperature rise and has a viscosity lowering excessively, insulating board 7 cannot withstand the stress along the shearing direction, and shifts along the shearing direction. This shift is caused more at a periphery of insulating board 7, and is caused more in the board 7 of the multilayer wiring board having a larger size.

However, the multilayer wiring board in accordance with this embodiment includes insulating board 7 including the core and the thermosetting resin which can hold the core at the minimum melting viscosity of the resin during the applying of heat and pressure. The insulating board 7 is prevented from shifting along the shearing direction, thus maintaining the shape of conductor 9.

The function of holding the core at the minimum melting viscosity of the thermosetting resin can be obtained by raising the lowest melting temperature of the thermosetting resin.

The lowest melting temperature of the thermosetting resin can be raised by preheating the thermosetting resin to adjust a hardness of the resin. The lowest melting temperature can be raised by mixing filler with the thermosetting resin. The filler may be selected in type, particle size, or adjusted in the amount of the filler to be mixed to adjust melting-hardening characteristics of the thermosetting resin.

The filler may employ inorganic material, such as alumina, silica, or aluminum hydroxide. An object of mixing of the filled with the thermosetting resin is to physically adjust a fluidity of the resin. The filler is not limited to the above materials as far as this object is achieved.

The filler has a particle diameter ranging preferably from 0.5 to 5 μm. The filler having the particle diameter within this range disperses into resin easily. During the applying of heat and pressure, the filler mixed with the thermosetting resin suppresses the lowering of the viscosity of the resin while maintaining a long melting time of the resin. As a result, wiring 10 is embedded while insulating board 7 is prevented from deforming along the shearing direction.

Conductor 4 provided in insulating board 7 preferably holds the core at the minimum melting viscosity of the thermosetting resin. When insulating board 7 is attached with the heat and pressure, a compression force applied to conductor 4 allows conductor 4 to exhibit the anchoring effect between wiring 12 and wiring 10 on double-sided wiring board 6.

In order to enhance the anchoring effect of conductor 4 to the core, conductors 4 provided at positions which do not influence a product design preferably have large diameter. A position which does not influence the product design is a position which has a low wiring density so that a wiring pattern (land) which contacts the conductor does not reduce entire accommodation for wirings even if the pattern (land) has a large diameter.

The expression, “product portion” means that a unit of product having electronic components mounted on the board to exhibit a circuit function. The product portion is incorporated into an electronic device.

Conductors 4 (anchoring conductors) for holding core 13 are also preferably provided at positions other than the product portion of the multilayer wiring board for the same reason discussed in Embodiment 1 with reference to FIG. 4.

During the process of applying heat and pressure, a shift between the pressing plate and the wiring material of the laminated body may be produced before a temperature rises to a shift starting temperature of board 7, namely, at a temperature lower than the shift starting temperature.

The shift starting temperature is the temperature at which insulating board 7 softens during the rising of the temperature due to the heat and shifts along the shearing direction due to a difference between respective thermal expansion properties of pressing plate 11 and double-sided wiring board 6 in the laminated body.

The shift between the pressing plate and the wiring material of the laminated body before a temperature rises to the shift starting temperature of board 7 absorbs the stress along the shearing direction applied to the insulating board temporarily at high temperatures. This prevents the conductor from deforming along the shearing direction.

The shift between the pressing plate and the wiring board during the temperature rise may be caused by applying a pressure smaller than the pressure applied at the minimum melting viscosity of the insulating board at a temperature lower than the shift starting temperature.

The pressure may be released for a predetermined time at a temperature lower than the shift starting temperature to allow the wiring to be embedded securely.

The surface of the pressing plate or the wiring material is finely roughened for reducing a contacting area microscopically, so that the shift between the wiring material and the pressing plate may be caused easily.

A sample will be described below. The insulating board is made of glass epoxy having a hardening start temperature ranging from 100 to 120° C. The pressing plate is made of a stainless steel having a thickness of 1 mm. This sample has a temperature raised to 80° C. under a pressure of 50 kg/cm², and then, the pressure is released for 10 minutes. After that, the temperature is raised to 200° C. under a pressure of 5 kg/cm². During the releasing of the pressure, this sample has a shift between the wiring material and the pressing plate. As a result, the laminated body is formed while the conductor is prevented from deforming along the shearing direction.

Pressing plate 11 preferably has a thermal expansion coefficient substantially identical to that of double-sided wiring board 6 at a temperature not higher than the shift starting temperature of insulating board 7.

Pressing plate 11 is made preferably of stainless steel, aluminum alloy, copper alloy, ceramic plate, and thus, is made of material having a thermal expansion coefficient substantially identical to that of double-sided wiring board 6.

Pressing plate 11 may preferably have a multilayer structure including a rigid portion provided at the surfaces of plate 11 and a thermal expansion adjusting portion in the pressing plate. This structure allows thermal expansion characteristics to be adjusted precisely, and thereby, reduces a small difference in thermal expansions between pressing plate 11 and the double-sided wiring board 6. This structure can prevent the conductor effectively from deforming along the shearing direction. The rigid portion may be preferably made of stainless steel. The thermal expansion adjusting section may be preferably made of a metal plate, a heat-resistant resin sheet, a ceramic sheet, or a composite sheet including fiber and resin.

The pressing plate may have the multilayer structure having the number of layers increase without bonding the layers to each other to absorb the stress, thereby suppressing the shift of the insulating board along the shearing direction. For instance, plural stainless steel plates stacked may cause shifts between the stainless steel plates, thereby absorbing, between the stainless steel plates, the shearing stress produced between the wiring material and the pressing plate.

As discussed above, according to this embodiment, the conductor is prevented from deforming along the shearing direction, hence providing the multilayer wiring board with preferable electrical connection and a high density.

According to Embodiment 2, the wiring materials and the insulating boards filled with the conductors are stacked on both surfaces of the double-sided wiring board, thereby providing the laminated body. For instance, two or more double-sided wiring boards may be stacked via insulating boards filled with conductors, thereby providing the laminated body. Alternatively, two or more double-sided wiring boards and wiring materials are stacked via the wiring materials and the insulating board filled with conductors, thereby providing the laminated body.

### EXEMPLARY EMBODIMENT 3

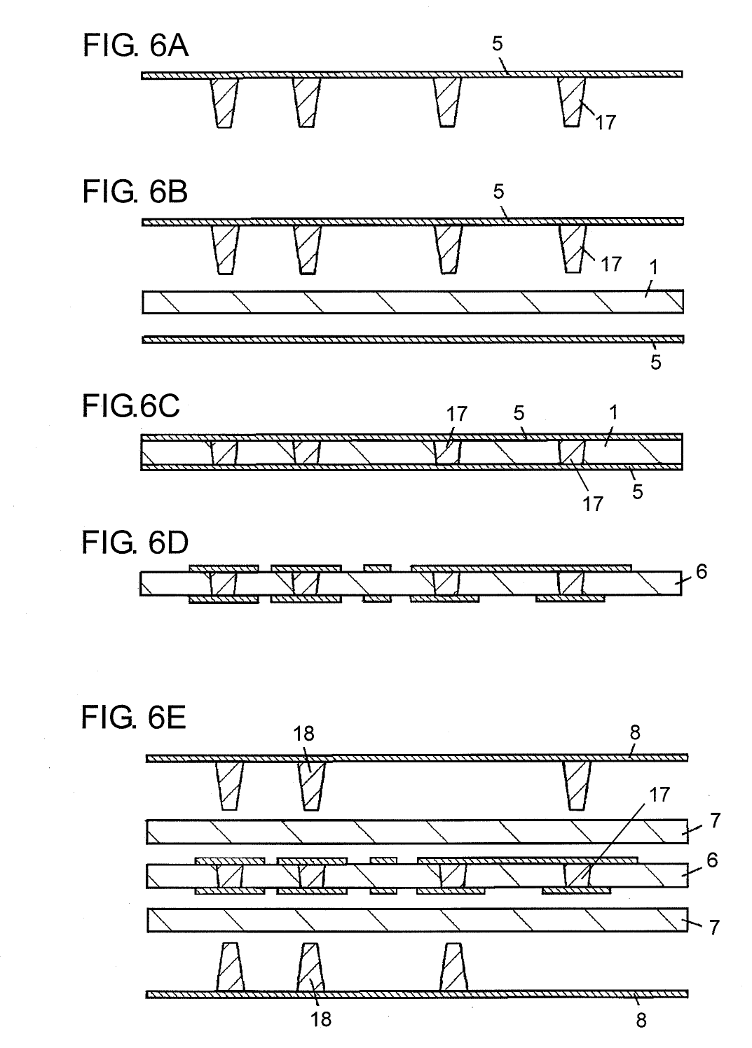

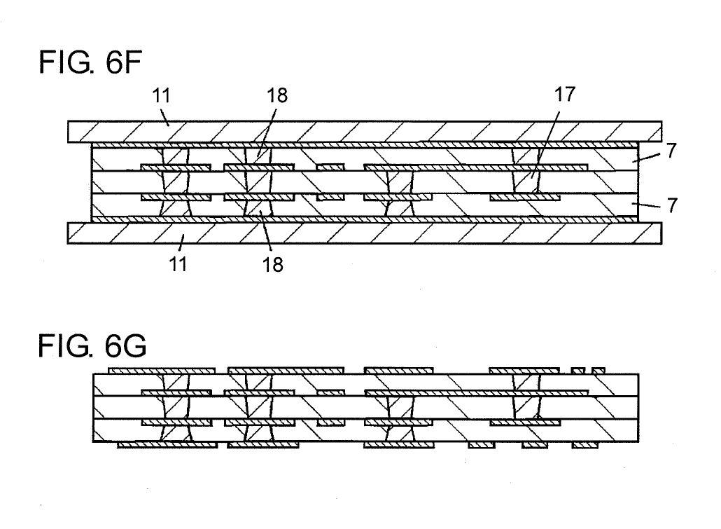

Another procedure for manufacturing the multilayer wiring board of the present invention will be described below with reference to FIGS. 6A to 6G. Components identical to those described above will be concisely described. Terms in the following description have been defined in Embodiment 1 or 2.

First, as shown in FIG. 6A, conductor 17 is formed on a surface of wiring material 5 made of metal foil, preferably copper foil having a surface roughened.

Conductor 17 is made of conductive paste including conductive particles and thermosetting resin, as described in Embodiment 1. Conductor 17 protrudes from wiring material 5 may be formed easily by screen printing.

The screen printing and drying may be repeated to provide conductor 17 with a sufficient height. For instance, the printing is repeated five times, thereby forming conductor 17 having a conical shape having a base of 0.3 mm Φ and a height of 3 mm thus having an aspect ratio of about 1.

Then, as shown in FIG. 6B, wiring material 5 having conductor 17 provided thereon, insulating board 1, and another wiring material 5 are stacked together. Insulating board 1 may be made from composite material of fiber and resin, or of film and adhesive provided on the film.

Then, as shown in FIG. 6C, heat and pressure are applied to allow conductor 17 to passing through insulating board 1, and to compress conductor 17 along the thickness direction, thereby electrically connecting between the wiring materials on both surfaces.

Then, wiring material 5 is etched to form a pattern, providing double-sided wiring board 6 shown in FIG. 6D.

Then, as shown in FIG. 6E, wiring material 8 with conductor 18 formed thereon by the process shown in FIG. 1, insulating board 7, and double-sided wiring board 6 are stacked, thereby providing a laminated body.

Next, as shown in FIG. 6F, the laminated body is sandwiched by pressing plates 11 vertically, and then, heat and pressure are applied to this laminated body. This allows conductor 18 to pass through insulating board 7 to electrically connect the wiring material 5 to the wiring material 8, and insulating board 7 is bonded to double-sided wiring board 6 and wiring material 8.

During the applying of heat and pressure, similarly to Embodiment 1, insulating board 7 changes in dimensions to follow the change of double-sided wiring board 6 in dimensions, and prevents a distortion in insulating board 7 produced along the shearing direction of insulating board 7, thereby preventing conductor 18 from deforming.

A method of allowing insulating board 7 to follow double-sided wiring board 6 is already described in Embodiment 1.

Next, wiring material 8 on the surface is patterned, thereby providing the multilayer wiring board shown in FIG. 6G.

As described above, conductor 18 is hardened before the applying of heat and pressure. Thereby, conductor 18 is rigid enough to have an anchoring effect of the conductor, hence reducing the shift in the insulating board along the shearing direction.

The method of manufacturing the multilayer wiring board in accordance with Embodiment 3 provides the multilayer wiring board with preferable electrical connection and a high density.

### EXEMPLARY EMBODIMENT 4

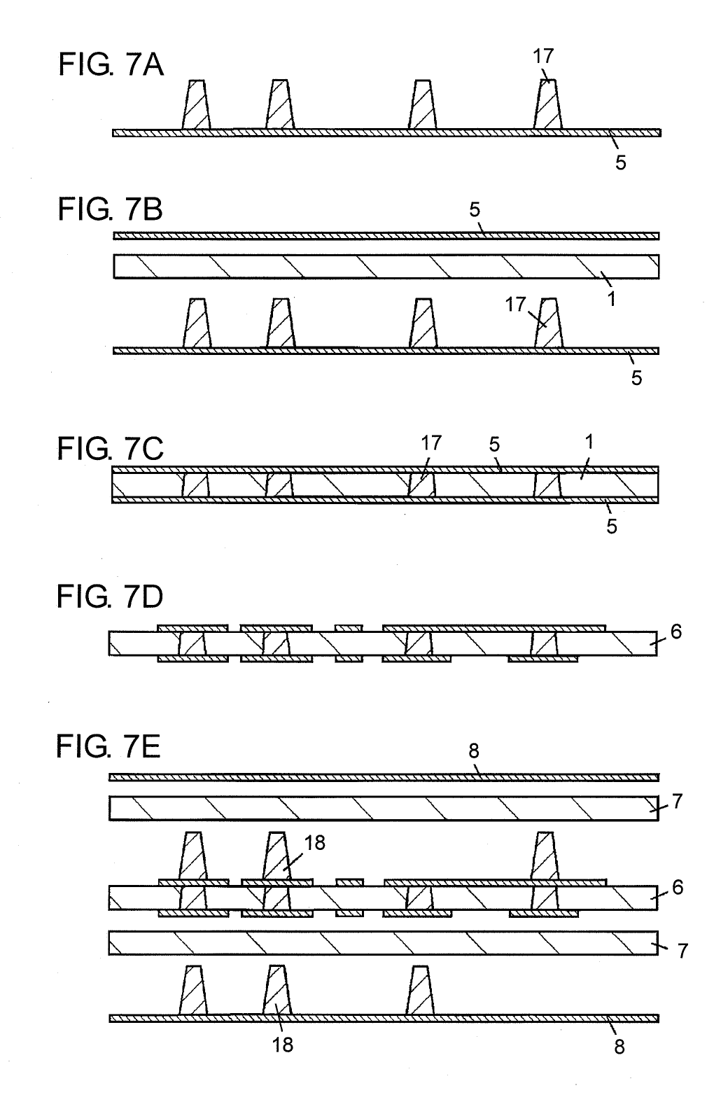

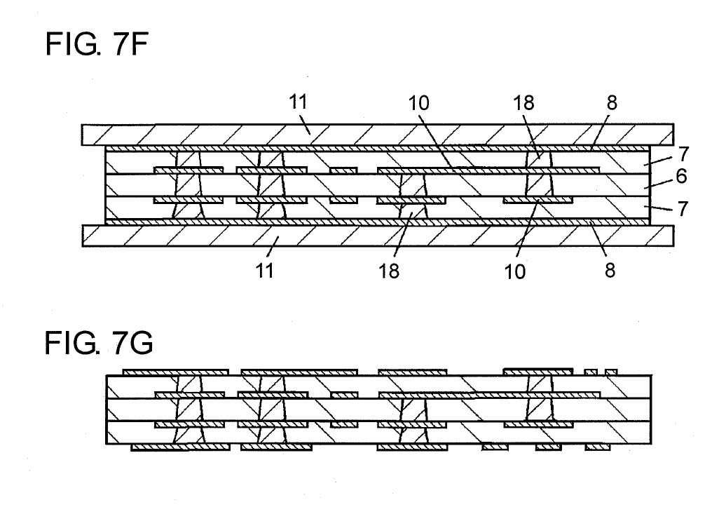

A further procedure of manufacturing the multilayer wiring board of the present invention will be described below with reference to FIGS. 7A to 7G. Components identical to those described above will be concisely described. Terms in the following description have been defined in Embodiment 1 or 2.

First, as shown in FIG. 7A, conductor 17 is formed on a surface of wiring material 5 made of metal foil, preferably of copper foil having a surface roughened. Conductor 17 may be made of the materials by the method as described in Embodiment 3.

Then, as shown in FIG. 7B, wiring material 5 having conductor 17 formed thereon, insulating board 1, and another wiring material 5 are stacked together. Insulating board 1 may be made of the same materials as described in Embodiment 3.

Then, as shown in FIG. 7C, heat and pressure are applied to allow conductor 17 to pass through board 1 and to compress conductor 17 along the thickness direction, thereby connecting the wiring materials on both surfaces of insulating board 1 electrically to each other. Next, wiring material 5 is patterned, thereby providing double-sided wiring board 6 shown in FIG. 7D.

Then, as shown in FIG. 7E, wiring material 8 having conductor 18 formed thereon by the process shown in FIG. 7A, insulating board 7, and double-sided wiring board 6 having conductor 18 formed on a surface thereof by the process shown in FIG. 7A are stacked together, thereby providing a laminated body.

Next, as shown in FIG. 7F, the laminated body is sandwiched by pressing plates 11 vertically, and then heat and pressure are applied to this laminated body to allow conductor 18 to pass through board 7, thereby electrically connecting wiring material 5 to wiring material 8, and bonding insulating board 7 to double-sided wiring board 6 and wiring material 8.

During the applying of heat and pressure, insulating board 7 changed in dimensions to follow the change of double-sided wiring board 6 in dimensions as described in Embodiment 1, and suppresses a distortion in insulating board 7 along the shearing direction of board 7, thereby preventing conductor 18 from deforming. A method of allowing the insulating board 7 to change to follow the change of double-sided wiring board 6 is described in Embodiment 1.

Next, wiring material 8 on the surface is patterned, providing the multilayer wiring board shown in FIG. 7G.

As discussed above, conductor 18 is hardened before the applying of heat and pressure. This increases the rigidity of conductor 18 and enhances the anchoring effect of the conductor, hence suppressing the shift in the insulating board along the shearing direction.

Conductor 18 can be formed not only on the wiring materials but also on the double-sided wiring board, so that the surfaces having conductors 18 formed thereon can face towards the same direction. The wiring board may not be necessarily turned over after forming the conductor, thus simplifying the manufacturing method.

As described above, the method of manufacturing the multilayer wiring board in accordance with this embodiment provides the multilayer wiring board with preferable electrical connection and a high density.

The double-sided wiring board of Embodiments 2 to 4 may be replaced with a multilayer circuit board, providing the same effects, in particular, providing the multilayer wiring board with a high density and stable electric connection.

In the wiring boards according to Embodiments 2 to 4, one laminated body is sandwiched by the pressing plates during the applying of heat and pressure to form the laminated body. However, the layered structure is not limited to this example. For instance, plural laminated bodies can be stacked via the pressing plates, and then, heat and pressure is applied to the bodies at once in order to increase the productivity, providing the same effects.

### EXEMPLARY EMBODIMENT 5

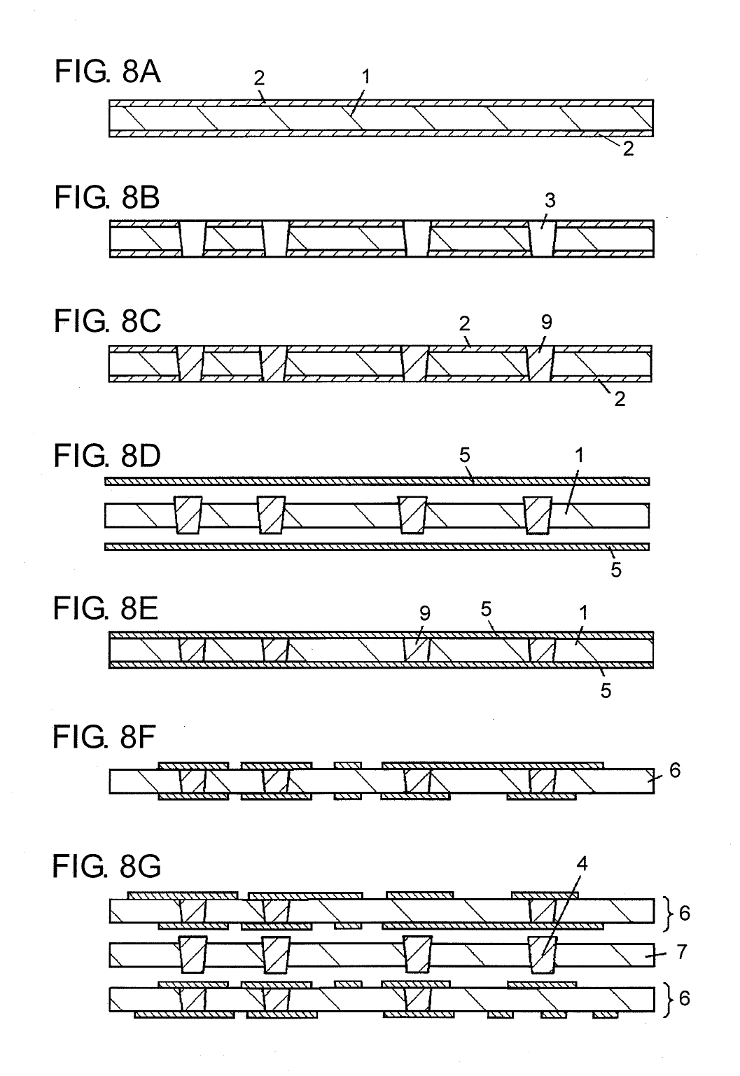

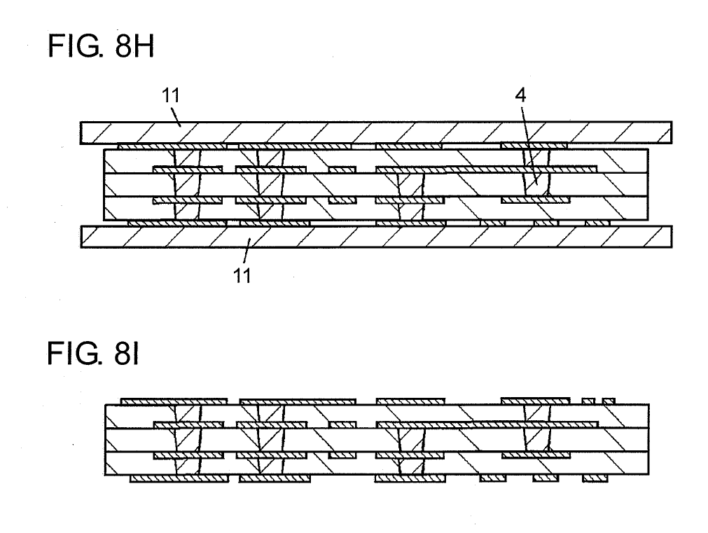

A further procedure of manufacturing the multilayer wiring board of the present invention will be described below with reference to FIGS. 8A to 8I. Components identical to those described above will be concisely described. Terms in the following description have been defined in Embodiment 1 or 2.

First, as shown in FIG. 8A, protective films 2 are attached onto both surfaces of insulating board 1. Insulating board 1 is made of composite material including a core and thermosetting resin similarly to the wiring board of Embodiment 1.

Then, as shown in FIG. 8B, through-hole 3 passing through protective films 2 and board 1 is formed.

Then, as shown in FIG. 8C, through-hole 3 is filled with conductor 9. Conductor 9 is preferably made of conductive paste for the reason described in Embodiment 1.

Next, protective films 2 from are peeled off from board 1, and wiring materials 5 are attached onto both surfaces of board 1, providing a board shown in FIG. 8D.

Then, as shown in FIG. 8E, heat and pressure are applied to wiring materials 5 so as to bond wiring materials 5 to both surfaces of board 1 and to compress conductor 9 along the thickness direction, thereby connecting the wiring materials on both surfaces of insulating board 1 electrically to each other.

Then, wiring materials 5 are patterned, thus providing double-sided wiring board 6 shown in FIG. 8F.

Then, as shown in FIG. 8G, insulating board 7 is placed between two double-sided wiring boards 6, thereby forming a laminated body. Insulating board 7 is formed by the processes shown in FIGS. 8A to 8D and filled with conductor 4.

Next, in the process shown in FIG. 8H, the laminated body is sandwiched by pressing plates 11 vertically, and heat and pressure are applied thereto, thereby bonding double-sided wiring boards 6 together via insulating board 7 between boards 6, thus providing the multilayer wiring board shown in FIG. 8I.

During the applying of heat and pressure, insulating board 7 changes in dimensions to follow the changes of double-sided wiring boards 6 in dimensions, and accordingly prevents from having a distortion in the insulating board along the shearing direction of the insulating board, accordingly preventing conductor 4 from deforming. A method of allowing the insulating board 7 to change to follow the change of double-sided wiring board 6 is described in Embodiment 1.

According to this embodiment, the same materials are placed on both surfaces of insulating board 7 and reduce a shifting stress produced in insulating board 7 along the shearing direction, accordingly allowing insulating board 7 changes to follow the change of double-sided wiring boards 6 more easily than the wiring board according to Embodiment 1.

As discussed above, according to this embodiment, the conductor is prevented from deforming along the shearing direction, providing a multilayer wiring board with preferable electrical connection and a high density.

### EXEMPLARY EMBODIMENT 6

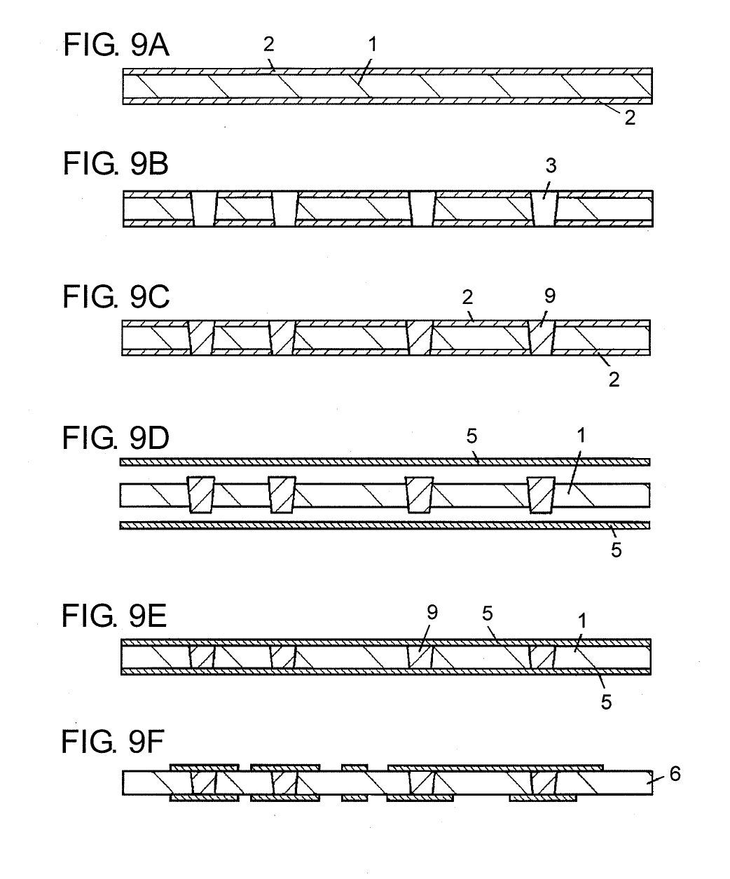

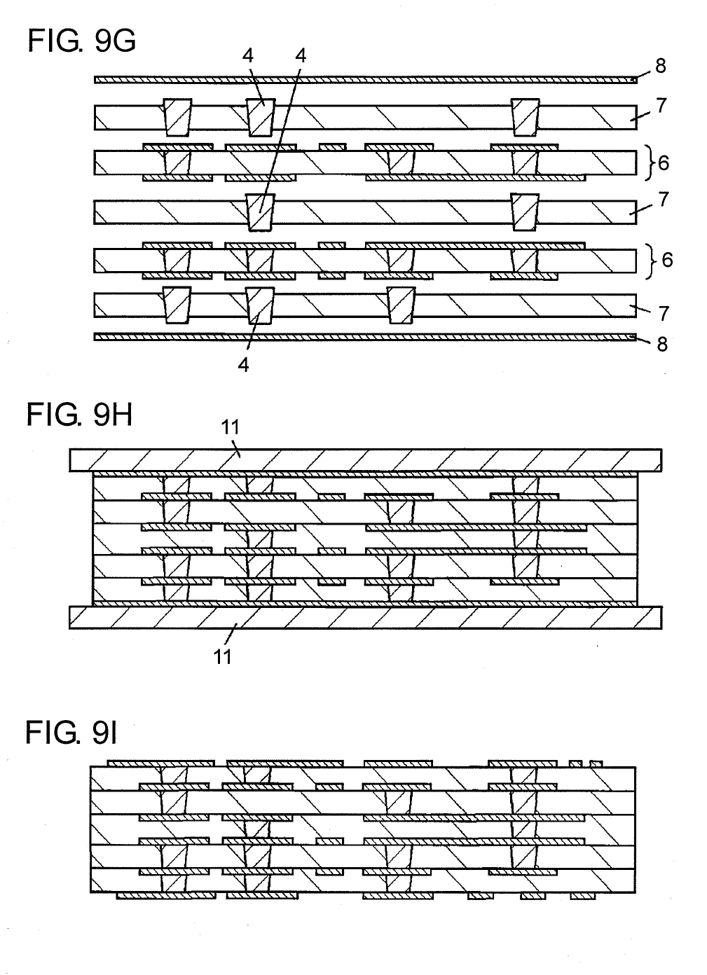

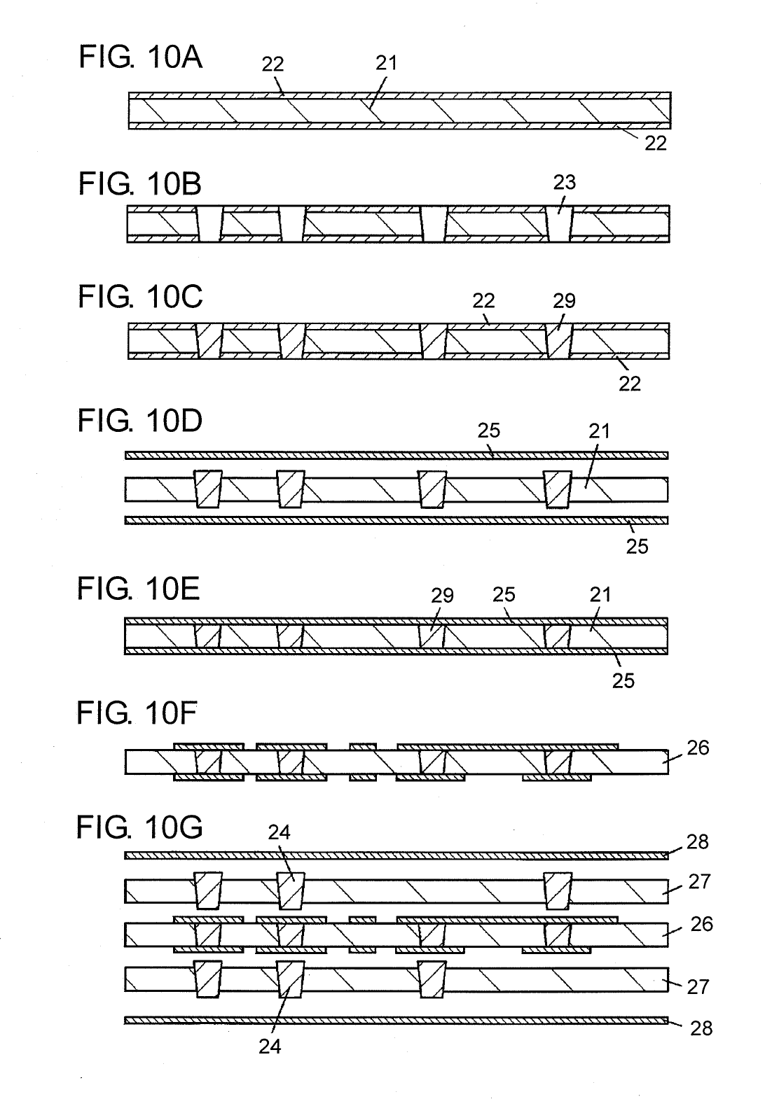

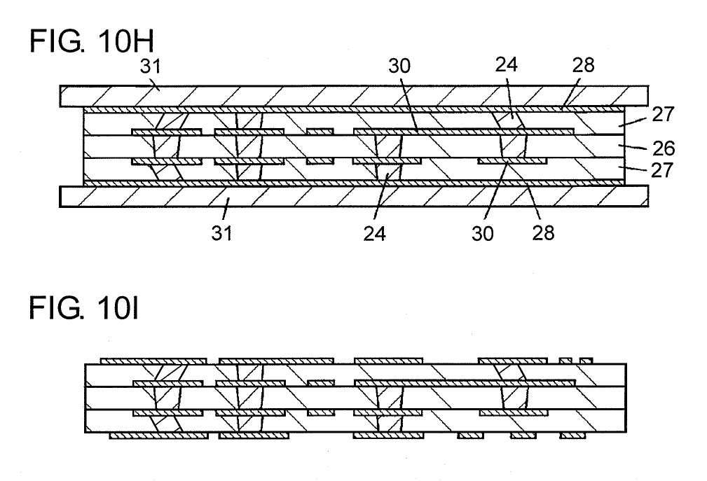

A further procedure of manufacturing the multilayer wiring board of the present invention will be described below with reference to FIGS. 9A to 9I. Components identical to those described above will be concisely described. Terms in the following description have been defined in Embodiment 1 or 2.

First, as shown in FIG. 9A, protective films 2 are provided on both surfaces of insulating board 1. Insulating board 1 is made of composite material including a core and thermosetting resin.

Than, as shown in FIG. 9B, through-hole 3 passing through protective films 2 and board 1 is formed. Then, as shown in FIG. 9C, through-hole 3 is filled with conductor 9. Conductor 9 is preferably made of conductive paste.

Next, protective films 2 are peeled off from insulating board 1, and wiring materials 5 are attached onto both surfaces of insulating board 1, thus providing a laminated body shown in FIG. 9D.

Then, as shown in FIG. 9E, heat and pressure are applied to wiring material 5 so as to bond wiring material 5 to both surfaces of insulating board 1 and to compress conductor 9 along the thickness direction, thereby allowing conductor 9 to connect electrically wiring materials 5 on both surfaces of insulating board 1 to each other.

Then, the wiring materials 5 are patterned, thus providing double-sided wiring board 6 shown in FIG. 9F.

Next, as shown in FIG. 9G, three insulating boards 7 are placed alternately between wiring materials 8 and double-sided wiring board 6, thereby forming a laminated body. Insulating boards 7 are made by the processes shown in FIGS. 9A to 9D and filled with conductor 4.

Then, as shown in FIG. 9H, the laminated body is sandwiched by pressing plates 11 vertically, and then, heat and pressure are applied thereto so as to bond wiring materials 8 together via double-sided wiring boards 6 and insulating boards 7 between materials 8. During the applying of heat and pressure shown in FIG. 9H, insulating boards 7 changes in dimensions to follow the change of double-sided wiring boards 6 in dimensions, and accordingly suppresses a distortion produced in insulating board 7 along the shearing direction of board 7, accordingly preventing conductor 9 from deforming. A method of allowing the insulating board 7 to change to follow the change of double-sided wiring board 6 is described in Embodiment 1.

Than, wiring materials 8 on both surfaces are patterned, thus providing the multilayer wiring board shown in FIG. 9I.

As discussed above, according to this embodiment, plural double-sided wiring boards are formed in advance. Then, a desired number of wiring boards are stacked via the insulating boards between the wiring boards, and then heated and pressed at once. As a result, the multilayer wiring board having preferable electrical connection and a high density is manufactured for a short time.

FIG. 9I shows the wiring board having six layers, however, the wiring board may have more number of double-sided wiring boards and insulating boards, providing the same effects.

The method of manufacturing the multilayer wiring board method in accordance with this embodiment provides the multilayer wiring board with preferable electrical connection and a high density.

The method of manufacturing the multilayer wiring board method in accordance with the present invention provides the multilayer wiring board with preferable electrical connection and a high density.

The double-sided wiring board described in Embodiments 5 to 6 may be replaced with a multilayer wiring board, providing the same effects, that ism providing the multilayer wiring board with a high density and providing the conductor to with stable electrical connection.

In the wiring boards according to Embodiments 5 and 6, one laminated body is sandwiched by the pressing plates during the applying of heat and pressure to form the laminated body. However, the layered structure is not limited to this example. For instance, plural laminated bodies can be stacked via the pressing plates, and then, heat and pressure is applied to the bodies at once in order to increase the productivity, providing the same effects.

### INDUSTRIAL APPLICABILITY

A multilayer wiring board and a method of manufacturing the board suppress a distortion produced in the insulating boards along a shearing direction of the insulating boards during the applying of heat and pressure to the insulating boards. This prevents conductors provided in the insulating boards from deforming, thereby providing the multilayer wiring board with preferable electrical connection. The conductors formed in the insulating boards do not deform along the shearing direction. This prevents the coordinate positions of the conductors from shifting, and allows a wiring pattern (land) contacting the conductors to have a small clearance, accordingly providing the multilayer wiring board with a high density. The wiring board according to the present invention is useful for a multilayer wiring board having a high density having an IVH structure in all layers connected by interlayer connection with conductors.

1. A multilayer wiring board comprising:
a first insulating board having a first wiring on a surface of the first board;
a second wiring facing the first insulating board; and
a second insulating board for bonding the first board to the second wiring,
wherein the first insulating board, the second wiring, and the second insulating board are stacked together by applying heat and pressure thereto,
wherein the first wiring and the second wiring are electrically connected to each other via a plurality of conductors passing through the second insulating board, and
wherein the conductors include an anchoring conductor.

2. The multilayer wiring board of claim 1, wherein the anchoring conductor has a diameter different from diameters of the conductors other than the anchoring conductor.

3. The multilayer wiring board of claim 1, further comprising a product portion which exhibits a circuit function to have an electronic component mounted thereto, wherein the anchoring conductor is provided at a position other than the product portion.

4. The multilayer wiring board of claim 1, wherein the plurality of conductors are made of conductive paste containing thermosetting resin which is hardened.

5. The multilayer wiring board of claim 4, wherein the conductive paste including thermosetting resin is hardened during the applying of heat and pressure.

6. The multilayer wiring board of claim 4, wherein the conductors are hardened before the applying of heat and pressure.

7. The multilayer wiring board of claim 1,
wherein the second insulating board includes a core and a thermosetting resin, the thermosetting resin has a viscosity which, during the applying of heat and pressure, lowers to a minimum melting viscosity during the applying of heat and pressure and then rises while the thermosetting resin hardens, and
wherein the minimum melting viscosity allows the conductors to hold the core.

8. The multilayer wiring board of claim 1, wherein the first insulating board is a multilayer circuit board.

9. The multilayer wiring board of claim 8, wherein the conductors passing through all layers of the multilayer circuit board.

10. A method of manufacturing a multilayer wiring board, comprising:
forming a through-hole passing through an insulating board;
filling the through-hole with a conductor;
forming a laminated body which includes a double-sided wiring board, the insulating board on the double-side wiring board, and a wiring material on the insulating board;
applying heat and pressure to the laminated body for electrically connecting a wiring of the double-sided wiring board to the wiring material via the conductor; and
forming a further through-hole for forming an anchoring conductor simultaneously during said forming of the through-hole.

11. A method of manufacturing a multilayer wiring board, comprising:
forming a conductor on a wiring material;
forming a laminated body which includes the wiring material, an insulating board on the wiring material, and a double-sided wiring board on the insulating board;
applying heat and pressure to the laminated body for electrically connecting a wiring of the double-sided wiring board to the wiring material via the conductor;
patterning the wiring material; and
forming an anchoring conductor simultaneously during said forming of the conductor,

12. The method of claim 11, further comprising
forming a first wiring material in advance on the double-sided wiring board,
wherein said forming of the conductor comprises forming the conductor on the first wiring material formed on the double-sided wiring board, and
wherein said forming of the laminated body comprises stacking the double-sided wiring board, the insulating board, and a second wiring material together.

13. The method of claim 10,
wherein the insulating board includes a core and a thermosetting resin,
wherein a viscosity of the thermosetting resin lowers to a minimum melting viscosity during said applying of the heat and the pressure and then rises while the resin hardens, and
wherein the minimum melting viscosity allows the conductor to hold the core.

14. The method of claim 10,
wherein said applying of the heat and the pressure comprises applying the heat and the pressure to the laminated body via a pressing plate,
said method further comprising producing a shift between the laminated body and the pressing plate before a temperature reaches a shift starting temperature, and
wherein the shift starting temperature is a temperature at which the shift occurs in the laminated body along a shearing direction due to a difference between thermal expansion properties of the pressing plate and the double-sided wiring board when the insulating board softens due to a temperature rise by applying of the heat.

15. The method of claim 14, wherein said producing of the shift comprises applying a pressure lower than a pressure applied to the insulating board at the minimum melting viscosity.

16. The method of claim 10,
wherein said applying of the heat and the pressure comprises applying the heat and the pressure to the laminated body via a pressing plate, and
wherein the pressing plate has a thermal expansion coefficient substantially identical to a thermal expansion coefficient of the double-sided wiring board.

17. The method of claim 16, wherein the pressing plate has a multilayer structure including a rigid portion and a thermal expansion adjusting portion, the rigid portion being provided at a surface of the pressing plate, the thermal expansion adjusting portion being provided in the pressing plate.

18. The method of claim 10, wherein the double-sided wiring board comprises a multilayer circuit board.

19. The method of claim 10, further comprising
patterning the wiring material after said applying of the heat and the pressure,
wherein during said applying of the heat and the pressure, the insulating board changes in dimensions to follow a change of the double-sided wiring board in dimensions.

20. The method of claim 10,
wherein at least two sheets of the double-sided wiring board are layered together via the insulating board, and
wherein during said applying of the heat and the pressure, the insulating board changes in dimensions to follow changes of the double-sided wiring board and the further double-sided wiring board in dimensions.

21. The method of claim 10,
wherein at least two sheets of the double-sided wiring board and the wiring material are layered together via the insulating board, and
wherein during said applying of the heat and the pressure, the insulating board changes to follow a change of the double-sided wiring board in dimensions.

22. The method of claim 11,
wherein the insulating board includes a core and a thermosetting resin,
wherein a viscosity of the thermosetting resin lowers to a minimum melting viscosity during said applying of the heat and the pressure and then rises while the resin hardens, and
wherein the minimum melting viscosity allows the conductor to hold the core.

23. The method of claim 12,
wherein the insulating board includes a core and a thermosetting resin,
wherein a viscosity of the thermosetting resin lowers to a minimum melting viscosity during said applying of the heat and the pressure and then rises while the resin hardens, and
wherein the minimum melting viscosity allows the conductor to hold the core.

24. The method of claim 11,
wherein said applying of the heat and the pressure comprises applying the heat and the pressure to the laminated body via a pressing plate,
said method further comprising producing a shift between the laminated body and the pressing plate before a temperature reaches a shift starting temperature, and
wherein the shift starting temperature is a temperature at which the shift occurs in the laminated body along a shearing direction due to a difference between thermal expansion properties of the pressing plate and the double-sided wiring board when the insulating board softens due to a temperature rise by applying of the heat.

25. The method of claim 12,
wherein said applying of the heat and the pressure comprises applying the heat and the pressure to the laminated body via a pressing plate,
said method further comprising producing a shift between the laminated body and the pressing plate before a temperature reaches a shift starting temperature, and
wherein the shift starting temperature is a temperature at which the shift occurs in the laminated body along a shearing direction due to a difference between thermal expansion properties of the pressing plate and the double-sided wiring board when the insulating board softens due to a temperature rise by applying of the heat.

26. The method of claim 11,
wherein said applying of the heat and the pressure comprises applying the heat and the pressure to the laminated body via a pressing plate, and
wherein the pressing plate has a thermal expansion coefficient substantially identical to a thermal expansion coefficient of the double-sided wiring board.

27. The method of claim 12,
wherein said applying of the heat and the pressure comprises applying the heat and the pressure to the laminated body via a pressing plate, and
wherein the pressing plate has a thermal expansion coefficient substantially identical to a thermal expansion coefficient of the double-sided wiring board.

28. The method of claim 11, wherein the double-sided wiring board comprises a multilayer circuit board.

29. The method of claim 12, wherein the double-sided wiring board comprises a multilayer circuit board.

30. The method of claim 11, further comprising
patterning the wiring material after said applying of the heat and the pressure,
wherein during said applying of the heat and the pressure, the insulating board changes in dimensions to follow a change of the double-sided wiring board in dimensions.

31. The method of claim 12, further comprising
patterning the wiring material after said applying of the heat and the pressure,
wherein during said applying of the heat and the pressure, the insulating board changes in dimensions to follow a change of the double-sided wiring board in dimensions.

32. The method of claim 11,
wherein at least two sheets of the double-sided wiring board are layered together via the insulating board, and
wherein during said applying of the heat and the pressure, the insulating board changes in dimensions to follow changes of the double-sided wiring board and the further double-sided wiring board in dimensions.

33. The method of claim 12,
wherein at least two sheets of the double-sided wiring board are layered together via the insulating board, and
wherein during said applying of the heat and the pressure, the insulating board changes in dimensions to follow changes of the double-sided wiring board and the further double-sided wiring board in dimensions.

34. The method of claim 11,
wherein at least two sheets of the double-sided wiring board and the wiring material are layered together via the insulating board, and
wherein during said applying of the heat and the pressure, the insulating board changes to follow a change of the double-sided wiring board in dimensions.

35. The method of claim 12,
wherein at least two sheets of the double-sided wiring board and the wiring material are layered together via the insulating board, and
wherein during said applying of the heat and the pressure, the insulating board changes to follow a change of the double-sided wiring board in dimensions.
